(19) United States
(12) Patent Application Publication
(10) Pub. No.: US 2006/0281274 A1
(43) Pub. Date: Dec. 14, 2006

(54) Nonvolatile resistive memory element

(76) Inventor: Martin Verhoeven, Radebeul (DE)

Correspondence Address: EDELL, SHAPIRO & FINNAN, LLC, 1901 RESEARCH BOULEVARD, SUITE 400, ROCKVILLE, MD, 20850, US

(21) Appl. No.: 11/284,127

(22) Filed: Nov. 22, 2005

(30) Foreign Application Priority Data
Nov. 26, 2004 (DE) 10 2004 057 236.4

(51) Int. Cl. H01L 27/148; H01L 21/331

(52) U.S. Cl. 438/309; 257/225

(57) ABSTRACT

A nonvolatile memory element includes a first material region, a second material and an oxidation material region including an oxidation material as a memory material region. The oxidation material includes an oxidized form of the first material and/or an oxidized form of the second material. The first material is selected such that its oxidized form is formed in comparatively high-resistance fashion. The second material is selected such that its oxidized form is formed in comparatively low-resistance fashion.

### CROSS REFERENCE TO RELATED APPLICATIONS

This Application Claims Priority Under 35 USC §119 To German Application No. 10 2004 057 236.4, Filed On Nov. 26, 2004, and titled “Nonvolatile Resistive Memory Element, Method for Producing it and Method for Operating it”, the entire contents of which are hereby incorporated by reference.

### FIELD OF THE INVENTION

The present invention relates to a nonvolatile resistive memory element, a method for producing it, and a method for operating it. The invention relates in particular to a nonvolatile memory cell of the MIM* type.

### BACKGROUND

In the further development of modern memory technologies, the main emphasis is on not only a maximum integration density to be achieved for the memory elements but also the development of nonvolatile memory concepts. Therefore, in the past, various memory conceptions of this type have been devised for nonvolatile information storage on the basis of semiconductor components, in particular including so-called flash memory cells. In the case of such flash memory cells of the resistive type, different information contents are defined by means of different nonreactive resistances or conductivities of a material region. However, known concepts for nonvolatile resistive memory cells of this type operate slowly, e.g. compared with volatile memory technologies, and, moreover, have been insufficiently miniaturized hitherto. In addition, conventional concepts have, with regard to their architecture, a complexity that is not to be underestimated in the production sequence.

### SUMMARY

An object of the invention is to provide a nonvolatile resistive memory cell and also a corresponding production method that are achieved in a particularly simple but reliable manner in conjunction with reduced complexity of the cell architecture.

The above and further objects are achieved in accordance with the present invention with a nonvolatile resistive memory element that comprises a first material region including an electrically conductive first material, a second material region including an electrically conductive second material and an oxidation material region between and in direct mechanical and electrical contact with the first and second material regions and including an oxidation material as memory material region. The oxidation material is formed or can be formed from an oxidized form of the first material and/or an oxidized form of the second material in which the first material is chosen such that the oxidized form of the first material is electrically of comparatively high resistance or electrically insulating, and in which the second material is chosen such that the oxidized form of the second material is electrically of comparatively low resistance or electrically conductive.

It is a central idea of the present invention to provide the memory material region of the nonvolatile resistive memory element according to the invention from an oxidation material region including an oxidation material, in which case the oxidation material is formed or can be formed from an oxidized form of the first material and/or from an oxidized form of the second material, and in which case the oxidized form of the first material is electrically of comparatively high resistance or electrically insulating and the oxidized form of the second material is electrically of comparatively low resistance or electrically conductive. This results, according to the invention, in the possibility of achieving, through the choice or the setting of the proportions of the oxidized form of the first material or of the oxidized form of the second material in the oxidation material region, a corresponding variation in the total electrical resistance or the total electrical conductivity and hence a corresponding coding for information contents by way of the conductivity or the resistance.

On account of their electrical conductivities, the first material region and the second material region function as access electrodes to the memory material region.

In one embodiment of the memory element according to the invention, the proportion of the oxidized form of the first material and of the oxidized form of the second material in the oxidation material region can be changed by applying an electrical potential difference to the memory element.

In a further embodiment of the memory element according to the invention, the proportion of the oxidized form of the first material and of the oxidized form of the second material in the oxidation material region can be changed by causing an electric current to flow via the memory element.

In another embodiment of the memory element according to the invention, the proportions of the oxidized form of the first material and of the oxidized form of the second material in the oxidation material region can be formed in reversible fashion.

It is particularly advantageous to have different total resistances or total conductivities of the memory material region that can be set via setting different proportions of the oxidized form of the first material and of the oxidized form of the second material in the oxidation material region.

It is furthermore advantageous to have different memory states or stored information states that can be assigned or are assigned to different values or ranges of values for the total resistance or for the total conductivity of the memory material region.

The first material may be, e.g. aluminum. For example, the oxidized form of the first material may be Al₂O₃.

The second material may be silver. For example, the oxidized form of the second material may be AgO.

In another embodiment of the memory element according to the invention, the proportion of the oxidized form of the first material in the oxidation material region can be changed essentially at a first interface between the first material region and the oxidation material region.

In still another embodiment of the memory element according to the invention, the proportion of the oxidized form of the second material in the oxidation material region can be changed essentially at a second interface between the second material region and the oxidation material region.

It a particularly advantageous embodiment of the invention, upon reduction of the proportion of the oxidized form of the first material in the oxidation material region, the reduced proportion of the oxidized form of the first material can be formed as a constituent part of the first material region. In addition, or as an alternative, upon reduction of the proportion of the oxidized form of the second material in the oxidation material region, the reduced proportion of the oxidized form of the second material can be formed as a constituent part of the second material region.

A method for producing a nonvolatile resistive memory element in accordance with the invention comprises providing a first material region including an electrically conductive first material, a second material region including an electrically conductive second material and an oxidation material region between and in direct mechanical and electrical contact with the first and second material regions. The oxidation material region includes an oxidation material as memory material region, in which the oxidation material is formed or can be formed, from an oxidized form of the first material and/or an oxidized form of the second material. The first material is chosen such that the oxidized form of the first material is electrically of comparatively high resistance or electrically insulating, and the second material is chosen such that the oxidized form of the second material is electrically of comparatively low resistance or electrically conductive.

A method for operating a nonvolatile resistive memory cell according to the invention comprises setting different total resistances or total conductivities of the memory material region by setting different proportions of the oxidized form of the first material and of the oxidized form of the second material in the oxidation material region, and different memory states or stored information states can be assigned or are assigned to different values or ranges of values for the total resistance or for the total conductivity of the memory material region.

In one embodiment of the method for operating a nonvolatile resistive memory element according to the invention, the proportion of the oxidized form of the first material and of the oxidized form of the second material in the oxidation material region is changed by applying an electrical potential difference to the memory element.

In another embodiment of the method for operating a nonvolatile resistive memory element according to the invention, the proportion of the oxidized form of the first material and of the oxidized form of the second material in the oxidation material region is changed by causing an electric current to flow via the memory element.

The proportions of the oxidized form of the first material and of the oxidized form of the second material in the oxidation material region can be formed in reversible fashion. In addition, the proportion of the oxidized form of the first material in the oxidation material region to be changed essentially at a first interface between the first material region and the oxidation material region. Further, the proportion of the oxidized form of the second material in the oxidation material region to be changed essentially at a second interface between the second material region and the oxidation material region. Upon reduction of the proportion of the oxidized form of the first material in the oxidation material region, the reduced proportion of the oxidized form of the first material can be formed as a constituent part of the first material region. Upon reduction of the proportion of the oxidized form of the second material in the oxidation material region, the reduced proportion of the oxidized form of the second material can be formed as a constituent part of the second material region.

The invention provides, inter alia, an alternative structure for a nonvolatile memory cell and for a nonvolatile memory element of the resistive type. In particular, the architecture permits a higher processing speed and an improved integration, e.g. into existing conventional production methods for semiconductor memory technologies.

The present invention differs from the prior art in particular by virtue of the fact that known nonvolatile resistive memory elements and corresponding memory cells operate comparatively slowly and furthermore have a comparatively high complexity with regard to their construction.

The invention can be in the form of a MIM* structure where M represents aluminum in particular, I is an oxide layer, in particular a native aluminum oxide layer, and where M* is formed from or by silver. The MIM* device works by at least partially carrying out a conversion between aluminum oxide and silver oxide. Aluminum oxide is a material layer with good closure and insulating properties, whereas silver oxide is electrically conductive. The difference between states having high conductivity and low conductivity can be utilized to realize a corresponding first memory state or memory content “0” or a second memory state or memory content “1”. The conversion process with regard to the oxide material region can be assumed to be reproducible and reversible.

The conversion of aluminum oxide into silver oxide takes place at comparatively high field strengths of the electric field. It is assumed in this case that an oxygen atom at the interface between the aluminum oxide and the silver breaks a bond with aluminum in order to form a bond with silver. This can be imagined in particular in the sense of a tunneling process between two local energy minima (as is illustrated in FIGS. 4A and 4B described below).

On account of this rearrangement of the bond or the tunneling process, an electrical path with comparatively good conductivity is formed if a sufficient number of aluminum-oxygen bonds can be broken and a corresponding number of silver-oxygen bonds can be established. The opposite process can be expected if the electric current or the electrical potential and consequently the electric field strength are reversed. Furthermore, a conversion can also be expected with a rise in the temperature.

Aluminum oxide is more stable than silver oxide, which can occupy a lower energy level.

A central idea of the present invention includes providing, in a nonvolatile resistive memory cell or in a nonvolatile resistive memory element, a reversible and reproducible conversion between an insulation oxide, namely, e.g. an aluminum oxide and a conductive oxide, e.g. a silver oxide, at the interface between two different metals.

The above and still further objects, features and advantages of the present invention will become apparent upon consideration of the following detailed description of specific embodiments thereof, particularly when taken in conjunction with the accompanying drawings where like numerals designate like components.

### BRIEF DESCRIPTION OF THE DRAWINGS

FIGS. 1-3 depict schematic and sectional side views of a nonvolatile resistive memory cell with a corresponding resistive memory element according to the invention.

FIGS. 4A and 4B depict schematic graphical illustrations for demonstrating the energetic conditions in one embodiment of the nonvolatile resistive memory cell according to the invention and a corresponding nonvolatile resistive memory element.

### DETAILED DESCRIPTION

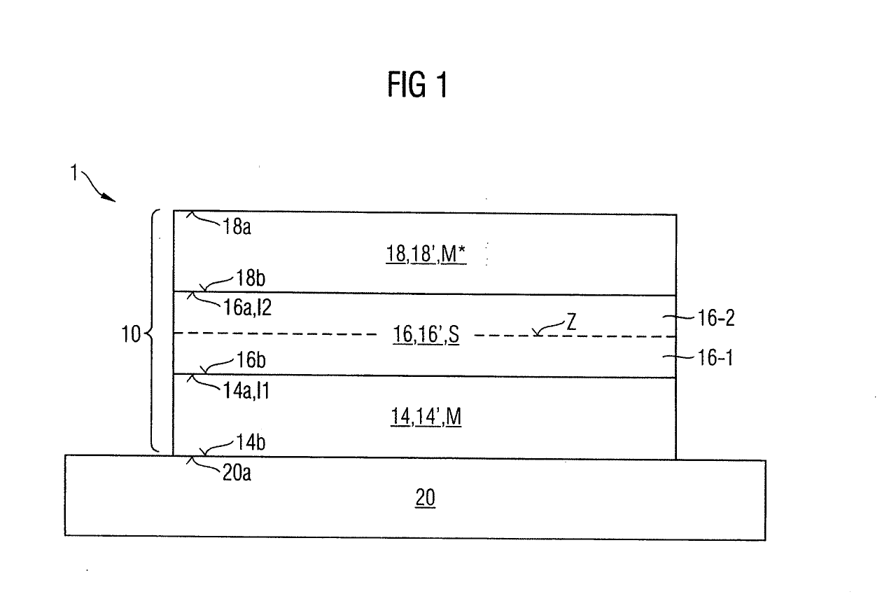

FIG. 1 is a schematic and sectional side view of one embodiment of a nonvolatile resistive memory cell 10, according to the invention, which is used and provided in a nonvolatile memory cell 1 or memory device.

On a substrate 20 having a surface region 20a, a first material region 14 is provided having or made of a first material 14′ as a first or bottom electrode, an oxidation material region 16 is provided having or made of an oxidation material 16′ as a memory material region S, and a second or top material region 18 is provided having or made of a second material 18′ as second electrode in this order on the surface region 20a of the substrate 20. What is necessary for the functioning of the first material region 14 and of the second material region 18 as respective bottom and top electrodes is the electrical conductivity of the respectively underlying first material 14′ and of the second material 18′. A first interface I1 toward the oxidation material region 16 is formed on the surface region 14a of the first material region 14. A corresponding second interface 12 toward the surface region 16a of the oxidation material region 16 is correspondingly formed at the underside 18b of the second material region 18. In the embodiment of FIG. 1, the first material 14′ of the bottom or first material region 14 is a first metal M, e.g. aluminum. The second material 18′ of the second or top material region 18 is e.g. a second metal M*, e.g. silver.

The oxidation material region 16 having the oxidation material 16′ is preferably formed by two proportions 16-1 and 16-2 which are arranged in this order on the surface region 14a or the first interface I1. In FIG. 1, the dotted line in the oxidation material region 16 designates an intermediate interface Z between the bottom proportion 16-1 and the top proportion 16-2 of the oxidation material region 16. According to the invention, the first or bottom proportion 16-1 of the oxidation material region 16 is formed by an oxidized form of the first material 14′ of the first or bottom material region 14, that is to say in particular by an oxide of the first metal M, that is to say e.g. by Al₂O₃. Correspondingly, according to the invention, the second proportion 16-2 of the oxidation material region 16 is formed by an oxidized form of the second or top material 18′ of the second or top material region 18, that is to say, e.g. by an oxide of the second metal M*, that is to say, e.g. by AgO.

The position of the intermediate interface Z in the oxidation material region 16 defines the size or thickness of the first and second proportions 16-1 and 16-2, respectively, in the entire oxidation material region 16. According to the invention, the first proportion 16-1 having or made of the oxidized form of the first material 14′ has a higher resistivity than the second proportion 16-2 of the oxidation material region 16 having or made of an oxidized form of the second material 18′. Consequently, the position of the intermediate interface Z and thus the thickness of the first and second proportions 16-1 and 16-2, respectively, in the entire oxidation material region 16 define and fix the total resistance over the memory element 10, so that an alteration of the proportions 16-1 and 16-2 or a shifting of the intermediate interface Z between the latter leads to a corresponding variation of the total electrical conductivity or the total electrical resistance over the memory element 10, which can be brought to correspondence with different memory contents or stored information states.

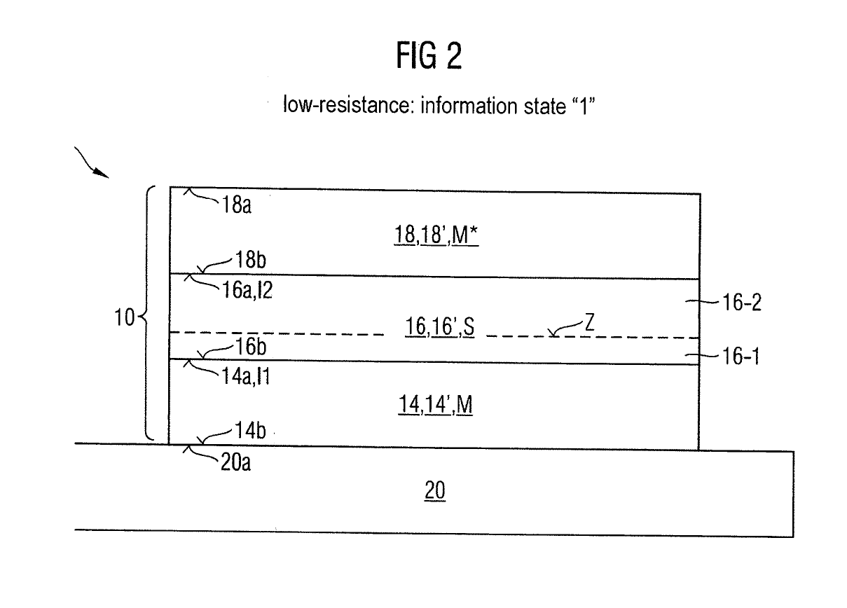

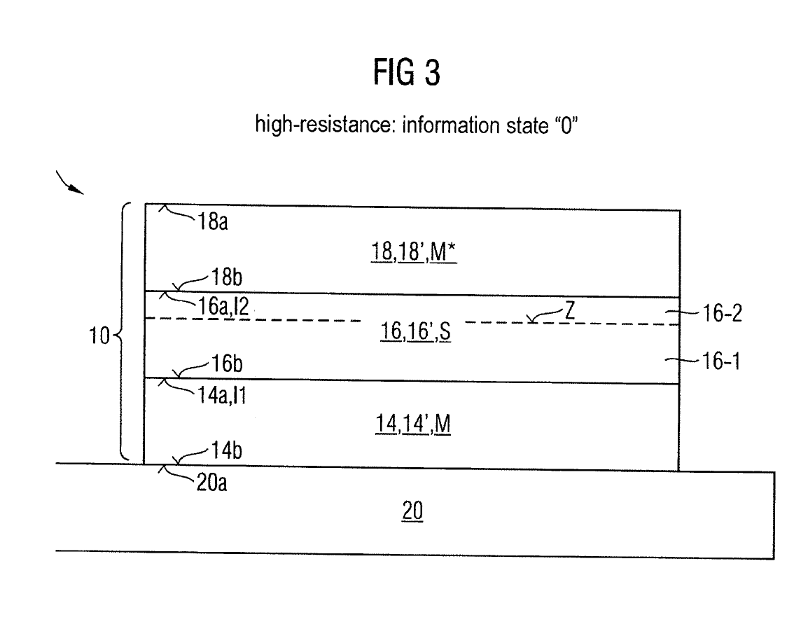

Each different information state and the physical representation thereof is illustrated in FIGS. 2 and 3. FIGS. 2 and 3 are likewise schematic and sectional side views of the embodiment of the nonvolatile resistive memory device 1 according to the invention with the nonvolatile resistive memory element 10 according to the invention as shown in FIG. 1, but the first and second proportions 16-1 and 16-2 in the entire oxidation material region 16 and consequently the position of the intermediate interface Z are fashioned differently. In FIG. 2, the first proportion 16-1 made of the high-resistance first material 14′ is formed in reduced fashion, so that its contribution to the total resistance of the memory element 10 is reduced and, consequently, a total electrical resistance having a comparatively low value is present, which can be brought to correspondence, e.g. with a memory state or information state “1”.

In the case of the embodiment of FIG. 3, by contrast, the first proportion 16-1 of the entire oxidation material region 16 is formed in increased fashion and the second proportion 16-2 is formed in reduced fashion, so that the total electrical resistance of the memory cell 1 according to the invention or of the memory element 1 according to the invention, as illustrated in FIG. 3, is formed rather in the range of high-value resistances, which corresponds to a memory state or information state “0”.

It goes without saying that finer subgradations than the distinction between high resistance and low resistance are also conceivable, so that in principle, the formation of more than two information states or memory states is also conceivable.

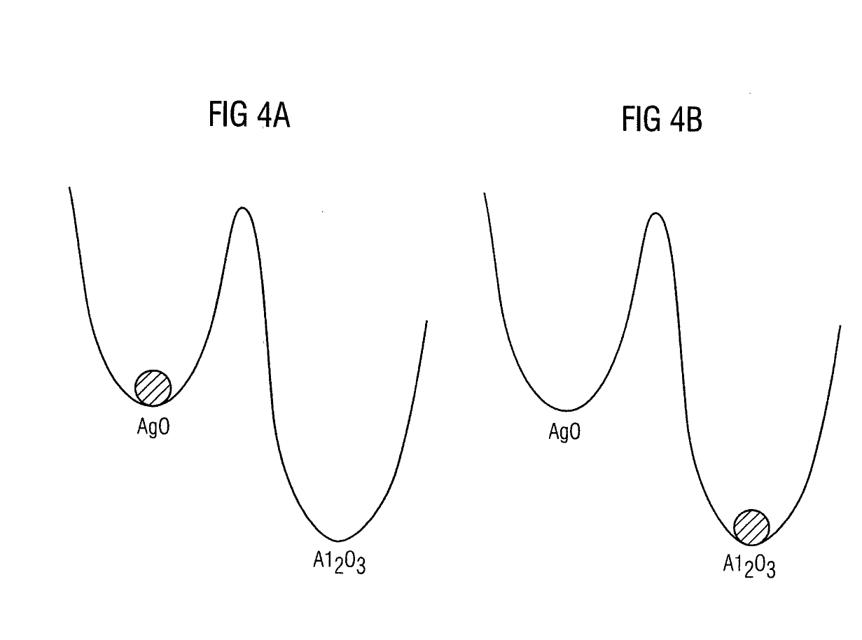

FIGS. 4A and 4B show on the basis of a model and in schematic form, the energetic conditions such as might be produced in the context of a tunneling process during the exchange of an oxygen bond or an oxygen atom when considering the transition of an oxygen atom O from the energy level for a bond between oxygen and silver, which is respectively illustrated on the left, to an energy level for a bond between oxygen and aluminum, which is respectively illustrated on the right. The bond between oxygen and aluminum is established at a lower energy level, so that, by means of a tunneling process of the energetic intermediate maximum illustrated in hatched fashion, a transition can take place between the two local energy minima for the bonding of oxygen to silver, respectively illustrated on the left, and for the bonding of oxygen to aluminum, respectively illustrated on the right.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

### LIST OF DESIGNATIONS

1 Memory cell according to the invention, memory device according to the invention
10 Memory element according to the invention
14 First or bottom material region, first or bottom material layer, first or bottom electrode
14a Surface region
14′ First or bottom material
16 Oxidation material region
16a Surface region
16′ Oxidation material
16-1 First proportion of the oxidation material region
16-2 Second proportion of the oxidation material region
18 Second or top material region, second or top material layer, second or top electrode
18a Surface region
18′ Second or top material
20 Substrate
20a Surface region
I1 First or bottom interface
I2 Second or top interface
M First metal
M* Second metal
S Memory material region
Z Intermediate interface

What is claimed:

1. A nonvolatile resistive memory element comprising a first material region including an electrically conductive first material, a second material region including an electrically conductive second material, and an oxidation material region disposed between and in direct mechanical and electrical contact with the first and second material regions, the oxidation material region including an oxidation material as a memory material region;
wherein the oxidation material is formed from at least one of an oxidized form of the first material and an oxidized form of the second material, the first material is selected such that the oxidized form of the first material is of high electrical resistance or is electrically insulating, and the second material is selected such that the oxidized form of the second material is of low electrical resistance or is electrically conductive.

2. The memory element of claim 1, wherein the oxidation material region is configured such that a proportion of the oxidized form of the first material and a proportion of the oxidized form of the second material in the oxidation material region are changed by applying an electrical potential difference to the memory element.

3. The memory element of claim 1, wherein the oxidation material region is configured such that a proportion of the oxidized form of the first material and a proportion of the oxidized form of the second material in the oxidation material region are changed by causing an electric current to flow via the memory element.

4. The memory element of claim 2, wherein proportions of the oxidized form of the first material and of the oxidized form of the second material in the oxidation material region are formed in reversible fashion.

5. The memory element of claim 3, wherein proportions of the oxidized form of the first material and of the oxidized form of the second material in the oxidation material region are formed in reversible fashion.

6. The memory element of claim 1, wherein different total resistances or total conductivities of the memory material region are set by setting different proportions of the oxidized form of the first material and of the oxidized form of the second material in the oxidation material region.

7. The memory element of claim 6, wherein different memory states or stored information states are assigned to different values or ranges of values for the total resistance or for the total conductivity of the memory material region.

8. The memory element of claim 1, wherein the first material comprises aluminum.

9. The memory element of claim 8, wherein the oxidized form of the first material is Al₂O₃.

10. The memory element of claim 1, wherein the second material comprises silver.

11. The memory element of claim 10, wherein the oxidized form of the second material is AgO.

12. The memory element of claim 1, wherein a proportion of the oxidized form of the first material in the oxidation material region is changed at a first interface between the first material region and the oxidation material region.

13. The memory element of claim 12, wherein a proportion of the oxidized form of the second material in the oxidation material region is changed at a second interface between the second material region and the oxidation material region.

14. The memory element of claim 13, wherein, upon reduction of the proportion of the oxidized form of the first material in the oxidation material region, the reduced proportion of the oxidized form of the first material is formed as a constituent part of the first material region.

15. The memory element of claim 14, wherein, upon reduction of the proportion of the oxidized form of the second material in the oxidation material region, the reduced proportion of the oxidized form of the second material is formed as a constituent part of the second material region.

16. A method for producing a nonvolatile resistive memory element, comprising:
providing a first material region including an electrically conductive first material, a second material region including an electrically conductive second material, and an oxidation material region disposed between and in direct mechanical and electrical contact with the first and second material regions, the oxidation material region including an oxidation material as a memory material region;
wherein the oxidation material is formed from at least one of an oxidized form of the first material and an oxidized form of the second material, the first material is selected such that the oxidized form of the first material is of high electrical resistance or is electrically insulating, and the second material is selected such that the oxidized form of the second material is of low electrical resistance or is electrically conductive.

17. A method for operating the nonvolatile resistive memory element of claim 1, comprising:
setting different total resistances or total conductivities of the memory material region by setting different proportions of the oxidized form of the first material and of the oxidized form of the second material in the oxidation material region; and
assigning different memory states or stored information states to different values or ranges of values for the total resistance or for the total conductivity of the memory material region.

18. The operating method as claimed in claim 17, wherein the proportion of the oxidized form of the first material and the proportion of the oxidized form of the second material in the oxidation material region are changed by applying an electrical potential difference to the memory element.

19. The operating method of claim 17, wherein the proportion of the oxidized form of the first material and the proportion of the oxidized form of the second material in the oxidation material region are changed by causing an electric current to flow via the memory element.

20. The operating method of claim 17, wherein the proportions of the oxidized form of the first material and of the oxidized form of the second material in the oxidation material region are formed in reversible fashion.

21. The operating method of claim 17, wherein the proportion of the oxidized form of the first material in the oxidation material region is changed at a first interface between the first material region and the oxidation material region.

22. The operating method of claim 17, wherein the proportion of the oxidized form of the second material in the oxidation material region is changed at a second interface between the second material region and the oxidation material region.

23. The operating method of claim 17, wherein, upon reduction of the proportion of the oxidized form of the first material in the oxidation material region, the reduced proportion of the oxidized form of the first material is formed as a constituent part of the first material region.

24. The operating method of claim 17, wherein, upon reduction of the proportion of the oxidized form of the second material in the oxidation material region, the reduced proportion of the oxidized form of the second material is formed as a constituent part of the second material region.
